(19) United States
(12) Patent Application Publication
(10) Pub. No.: US 2003/0214912 A1
(43) Pub. Date: Nov. 20, 2003

(54) System and method for the management of procurement and provisioning of video transmission services

(76) Inventors: Tenzin Khangsar, Longueil (CA); Rene Bellei, Beaconsfield (CA)

Correspondence Address: BAKER & HOSTETLER LLP, Washington Square, Suite 1100, 1050 Connecticut Avenue, N.W., Washington, DC, 20036, US

(21) Appl. No.: 10/384,695

(22) Filed: Mar. 11, 2003

(30) Foreign Application Priority Data
Mar. 11, 2002 (CA) 2,375,377

(51) Int. Cl. H04N 7/16; H04L 1/00; H04J 1/16; H04J 3/14; G06F 11/00; H04L 12/26; G08C 15/00; G01R 31/08

(52) U.S. Cl. 370/238; 725/1

(57) ABSTRACT

The present invention concerns a system for the management of procurement and provisioning of video transmission services. The system includes a database containing information related to video transmission services provided by a video service provider for a plurality of video service providers, a routing engine operatively associated with the database for calculating at least one route for routing a video service between video service providers based on selectable criteria, a cost engine operatively associated with the database for calculating a cost associated with each of the routes calculated by the routing engine, an ordering module for entering the criteria and a video transmission coordination module for delivering a video transmission service from origin to destination.

### FIELD OF THE INVENTION

The present invention relates to the field of broadcast communications, and more particularly to a system and method for managing procurement and provisioning of video transmission services from a plurality of video service providers.

### DESCRIPTION OF THE PRIOR ART

Telecommunications systems are used to provide many different types of broadcast telecommunications services. Broadcast telecommunications services are used by broadcasters to send and receive high quality television signals (news, sports, programming, etc.). From the video transmission of a football match to a live interview with the Pope, broadcasters buy a variety of services (“items”). Some of these items can be listed as follow: live positions, tape play out, standard conversion, uplink, downlink, turn around, space segment, fiber transport, etc. Companies that supply broadcast telecommunication services are known as Video Service Providers (VSP).

The video distribution system is extremely complex, with multiple networks owned by competitive VSPs communicating through shared switching facilities. These networks comprise multiple element types, including: terrestrial fibre networks, satellite networks, earth stations (up/down links), mobile earth stations, television switching centers, post production facilities and broadcasters. Each network has its own unique protocols, characteristics, pricing structure, relationships, etc., Generally, these characteristics are known only to the owners of the individual networks. A typical video transmission will require the participation of multiple transmission service providers, and thus crosses through multiple transmission networks. With current technology, establishing such a video transmission route requires manual intervention by multiple organizations since there is no consistent network model between multiple suppliers. Automation of this process is not possible without such a consistent model.

A broadcaster establishes relations with several VSPs to cover its video transmission services needs. Since news recognize no borders, video content comes from everywhere to everywhere in the world. Each time a video transmission is required, a broadcaster analyzes how many items they will require to successfully transmit the television signal. During this process, several communications are sent to the VSPs in order to find out what items they offer and what the price per item is. Currently, there is no existing standard or process to communicate those requirements or to answer to them. Several communications must happen between the broadcaster and the VSPs until all items are clearly identified and defined. Each item is a collection of technical parameters that indicates how the television signal is being treated and from where to where is going through. This collection of information is called “connectivity”.

Each item is also sold individually or as part of a bundle. A VSP will assign different set of rate cards to its items or bundles. Rate cards are time-sensitive—the longer the duration the higher the cost. Rate cards vary from VSP to VSP. VSPs will communicate to the broadcaster the rate card details per item. There is no existing standard or process to communicate the rate card information. The broadcaster will do its best to calculate the cost per item depending on the duration of the video transmission. Finally, the addition of all items will result in the final cost.

The booking stage starts once the broadcaster had agreed on the cost of the video transmission per item per VSP. The “booking” represents the actual confirmation/reservation of acquiring the items for a particular date, time and duration. The reservation of the item is particular to each VSP. Some may require a fax confirmation, others an email confirmation, others may have web-based system; others will accept a phone call confirmation, etc. If the broadcaster is not accredited with the VSP then a credit application form must be submitted before the booking. Each credit application is particular to each VSP. When one or some of the items are not available, VSPs will communicate to the broadcasters the next available window (date, time and duration when the item will become available). The broadcaster will receive this information in a variety of formats, each one particular to each VSP. With no existing standard processes, the broadcaster and the VSPs will do their best exchanging several communications with availability information about the different items until the broadcaster find the window where all items are available. Once all items are booked, each VSP will send a booking confirmation to the broadcaster. Some confirmations may require technical specifications. It is up to the broadcaster to ask for these specifications. The means of communication and the format of the booking confirmation are particular to each VSP. Even though each VSP has invested in complex scheduling systems to manage its assets, there is no existing standard or protocol to seamlessly pass the information from one system to another. There is no standard set of data defined in the video transmission industry.

All items must be lined up before the video transmission. The line up is the actual check that all items are ready to receive and transmit the signal. The higher the number of VSPs involved the more complex the video transmission becomes. The broadcaster will proceed to communicate with each VSP. All communications during the line up are via telephone calls. Some VSPs will accept to start the line up five minutes before the video transmission while others may accept more than ten minutes. The line up process before the transmission and all preventive and reactive actions taken by the broadcaster during the video transmission are commonly known as “transmission coordination”. If a problem is encountered with one of the VSPs (television signal is not received at the destination, audio is breaking up, video quality is not acceptable, etc.), the broadcaster will communicate with all of VSPs to make sure they can detect the problem and are ready to extend the duration of the video transmission if needed. During the telephone communications, all actions are done on an ad-hoc basis. There is no standard process to follow up the transmission coordination; neither there is a standard to communicate transmission problems. The video transmission success will depend on the experience of the personnel.

Several days, weeks or months after the video transmission occurred, the broadcaster will receive the different invoices from the VSPs. Each invoice will name the item sold to the broadcaster in a different way. There is no standard format for invoicing video transmission services. The broadcaster will go through a manual process to conciliate all costs and make sure that the estimated cost matches the actual one.

With world globalization and the need to communicate faster and better, broadcasters are looking forward to have seamless access to video transmission services. Other types of businesses are also looking forward to use video transmission services as a way to communicate better (telemedicine, corporate television, video-on-demand, etc.). With no standard process to manage the exchange of information between the Video Service Providers and the customers, the access to video transmission services is restricted to companies that have gone through the growing pains of doing video transmissions and are willing to accept the current quality of those services.

Attempts to automate the video transmission industry are ongoing at the individual and not industry level. For example, broadcasters have developed their own software applications to automate their internal management of video transmission resources. This software is only able to control the broadcaster's respective video transmission network and/or its video service provider of choice.

The same applies for VSPs. Some have developed their own software that can only automate the control of their very own video transmission network. However the benefits of automation are left behind as VSPs are forced to work with other VSPs with different automation (or lack of) practices.

Some VSPs have formed alliances, similar to the airline industry, and have committed to share common management platforms. However the incestuous and highly competitive nature of the video transmission industry prevents any meaningful industry wide automation of video transmission. In addition, alliances exclude many VSPs and do not offer any meaningful solution to automate the video transmission industry as a whole.

From a macro-perspective, VSPs are mainly made up of telecommunication companies who recognize that video transmission is not their core business. Even media companies have conceded that video transmission is mission-critical but not a core business such as the buying and selling of video content. As such, the video transmission industry finds itself in today's highly fragmented state with no incentive or support to become automated.

Video transmission hardware vendors have created impressive automation software to allow for the seamless control of their respective equipment. However the lack of interoperability between hardware vendors software programs, as well as competitive practices, prevents any meaningful industry level automation of video transmission services.

There is no universal strategy or automated solution to deal with the control of video transmissions from a plurality of video transmission service providers.

### SUMMARY OF THE INVENTION

It is an object of the invention to provide a system and method for permitting an integration of video services, and for providing an automated solution to the procurement and provisioning of video services. In accordance with the invention, this object is achieved with a system for the management of procurement and provisioning of video transmission services, comprising:

(a) a database containing information related to video transmission services provided by a video service provider for a plurality of video service providers;

(b) a routing engine operatively associated with said database for calculating at least one route for routing a video service between video service providers based on selectable criteria;

(c) a cost engine operatively associated with said database for calculating a cost associated with each of said at least one route calculated by said routing engine;

(d) an ordering module for entering said criteria; and

(e) a video transmission coordination module for delivering a video transmission service from origin to destination

### BRIEF DESCRIPTION OF THE DRAWINGS

The present invention and its advantages will be more easily understood after reading the following non-restrictive description of preferred embodiments thereof, made with reference to the following drawings in which:

FIG. 1 is a schematic representation of the system according to a preferred embodiment of the present invention;

FIG. 2 is a schematic representation of the system according to a preferred embodiment of the present invention, operatively connected to a plurality of electronic interfaces;

FIG. 3 is a schematic representation of the interoperability of two systems of the present invention;

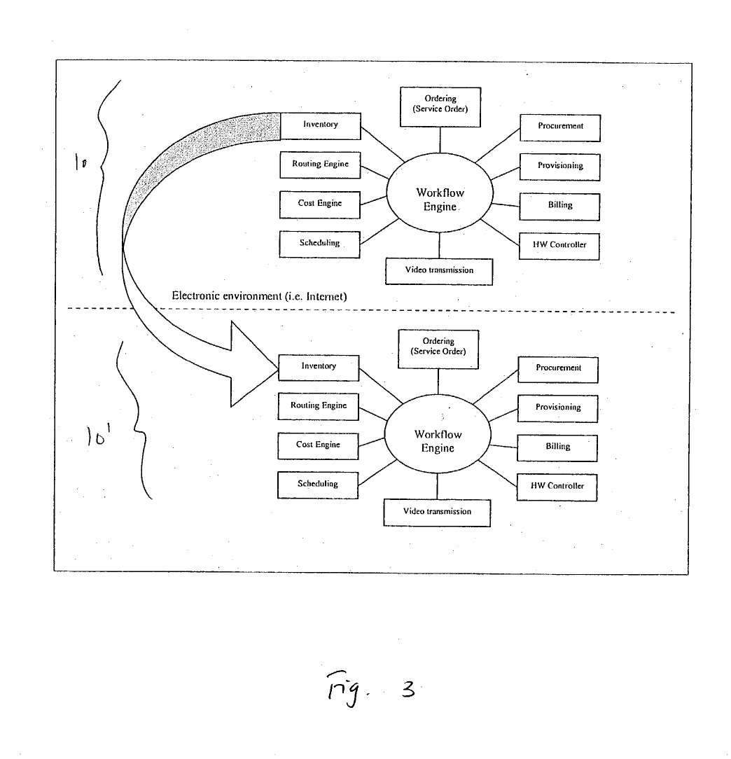

FIG. 4 is the data model class hierarchy for the Java Graph Framework used in the system of the present invention;

FIG. 5 is the utility class hierarchy for the Java Graph Framework used in the system of the present invention;

FIG. 6 is a schematic representation of different items offered by various VSPs, and illustrates how some VSPs can bundle more than one item;

FIG. 7 is a schematic representation of the flow of cost calculation per cost option;

FIG. 8 is a schematic representation of the video service universe, and illustrates how the system of the present invention interacts with all actors;

FIG. 9 is a representation of the criteria selectable by a client, the result of the analysis and the selection of a given option by a client.

### DESCRIPTION OF A PREFERRED EMBODIMENT OF THE INVENTION

### System Overview

The present invention provides a system and method for the management of procurement and provisioning of video transmission services from a plurality of video service providers.

For the purpose of the present invention, an operational process is a continued set of actions (sequence) performed intentionally in order to reach some result.

The present invention provides operational processes to support the procurement and provisioning of video transmission services. It is targeted to companies that perform the following activities:

1. Procure video transmission services from a plurality of Video Service Providers (the process of getting and analyzing cost and technical information from each VSP to provide routing and cost options based on particular requirements).

2. Provision video transmission services from a plurality of Video Service Providers (the process of scheduling and coordinating compatible services from each VSP to perform a video transmission based on particular requirements).

3. Provide video transmission services from a plurality of Video Service Providers to a customer base (the process of offer to sell and sell video transmission services from a plurality of Video Service Providers).

For the purpose of this invention, any company that performs the list of activities described above will be referred to herein as “organization”; any Video Service Provider will be referred to herein as “supplier”; and any customer of the organization will be referred to herein as “customer”.

The operational processes defined in this invention are centric to the organization. Although the maximum benefits are for the organization, the other parties (customers and VSPs) will also benefit from the operational processes by reducing the number of unnecessary communications and quality of service improvements. The following are the definition of actors per party:

1. The organization, as being the focus of this invention, has different actors, namely called Brokers:

a. Broker supplier relations: The broker supplier relation is responsible to turn a prospect supplier into a fully operational supplier as well as maintain the coverage of the video transmission service. To perform those responsibilities, the broker supplier gathers and maintains the supplier information (contact information, network data, cost information and conditions, operational policies), negotiates prices with suppliers when required (depends on broker marketing input) and maintains the routes and cost of the video transmission services.

b. Broker sales: The broker sales is responsible to turn a prospect into a customer as well as maintain the relations with customers. To effectively acquire sales, the broker sales interfaces with the customers and perform some operations on behalf of them (enter quotation, enter service order, etc.). The broker sales also performs the following operations: maintain relations with customer, maintain the customer information, promote the video transmission service (rate cards, special events) and get customer feedback.

c. Broker operation: The broker operation is responsible to manage the execution of a service order (provisioning) including: bookings, amendments, cancellation, transmission coordination, troubleshooting and reporting. To supervise/perform these activities, the broker operation is in contact with suppliers and customers. So if needed, the broker operation may update some supplier and customer information during the provisioning of video transmission services.

d. Broker accounting: The broker accounting is responsible to manage the receivables and payables of each transaction (service orders and bookings) including: billing, billing disputes, credits, cost conciliation and currency exchanges.

e. Broker marketing: The broker marketing is responsible to manage the overall video transmission service strategy: coverage (what should the organization cover?), cost (How much should the video transmission service cost?), price (How much should the organization charge for the video transmission service?) and discounts (What level of discounts should the organization grant to the customers?).

2. Actor supplier: This actor is responsible to supply contracted services to the broker. The supplier facilitates network and cost information to the broker. To effectively supply its services to the broker, the supplier maintains its contact information, network data, operational policies, cost information and conditions. Suppliers can be classified in two groups:

a. Network suppliers: A supplier that only facilitates its network, but do not offer services.

b. Service suppliers: A supplier that sell services using its own resources or other suppliers' resources.

3. Actor customer: This actor acquires video transmission services from the broker. To effectively acquire services from the broker, the customer maintains its contact information and connectivity profile. The customer interfaces through the broker to do these operations: enter quotation, view quotation, enter service order, view service order, enter service order amendment and enter service order cancellation. From quotation to service order and video transmission, the customer is fully informed along the procurement and provisioning of a video transmission services.

Each of the actors described in the previous paragraphs has access to certain actions. These actions are use cases. Each use case can be shared by more than one actor. Each operational process is defined by a sequence of use cases and the interaction between actors.

The operational processes/sequences are grouped as follows:

1. Procurement operational processes

a. Enter Quotation

b. Quotation processing

c. Manage Route

d. Sales management processes

i. Customer care

ii. Manage Customer

e. Supplier management processes

i. Cost reduction

ii. Manage Supplier

iii. Supplier care

f. Service management process

i. Manage Coverage

ii. Manage Discount

iii. Manage Special Events

iv. Market Intelligence

2. Provisioning operational processes

a. Enter Service Order

b. Enter Service Order Amendment

c. Enter Service Order Cancellation

d. Resource Not Available

e. Service Order Amendment

f. Service Order Cancellation

g. Service Order Processing

h. Service Order Rejection

i. Service Order Troubleshooting

j. Transmission Coordination

3. Billing operational processes

a. Receivables processes

i. Billing sequence

ii. Billing Dispute sequence

b. Payable processes

i. Payable sequence

ii. Payable Dispute sequence

To introduce the system and methods of the present invention, it is important to provide an overview of the process flow. The process flow goes from quotation and placing a service order to the actual video transmission coordination (service activation), troubleshooting and billing.

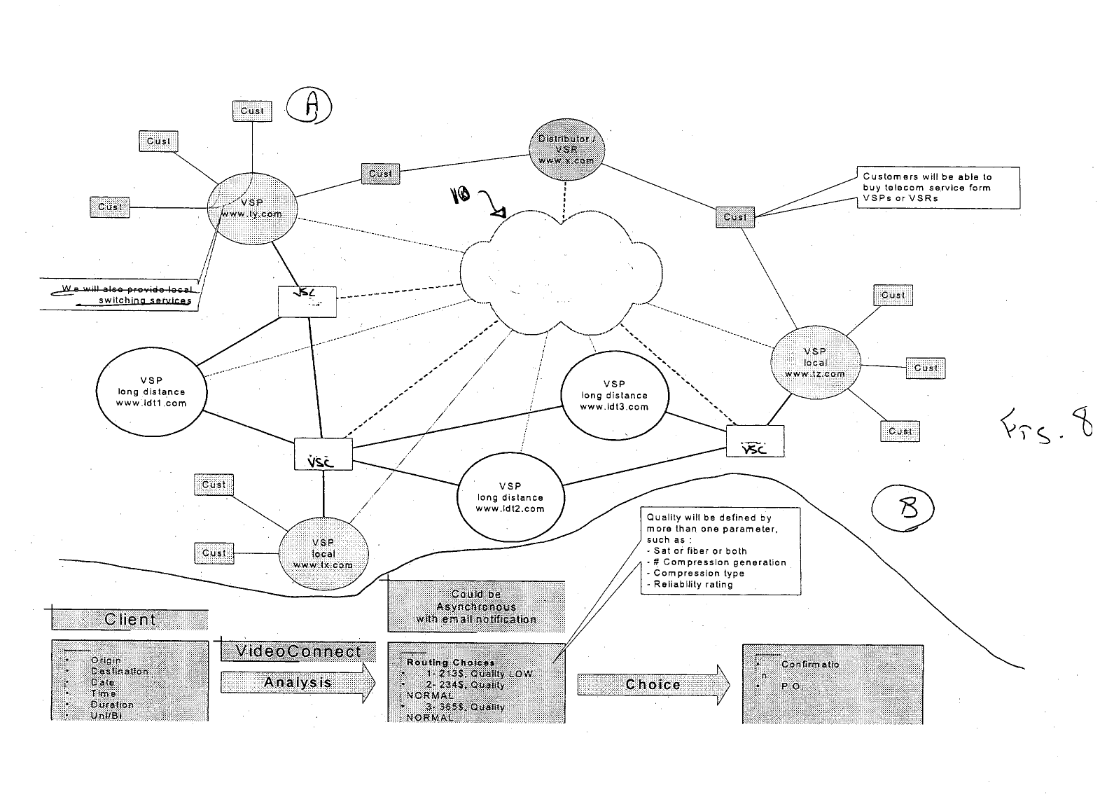

In this respect, and with reference to FIG. 8, the present invention provides a system 10 whereby a user can, in an automatic and integrated fashion, book a video transmission to originate at point A and terminate and point B for a given duration of time, at a given moment in time, without having to go through the tedious, manual process of the prior art. It can be seen that the system 10 is interconnected with all of the players of the video transmission universe, and thereby offers an integrated solution.

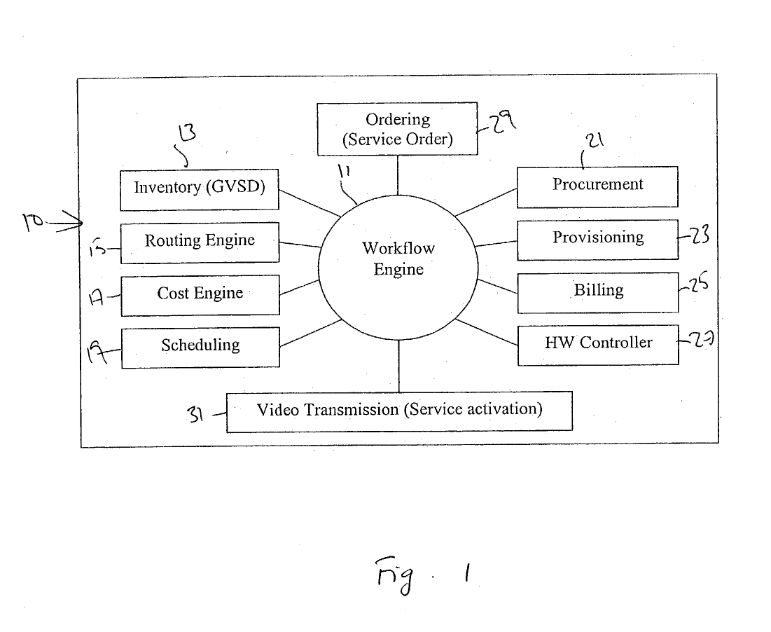

Referring now to FIG. 1, there is shown a schematic representation of the modules of the system 10 of the present invention.

The workflow engine 11 is the nucleus of the system. The workflow engine organizes and manages the flow of information between the system and the organization's workforce (employees) and even between disparate systems as appropriate. The workflow engine organizes business processes into task flows and their related subtasks, enabling the organization to manually or automatically complete tasks as needed. The workflow engine follows the operational process of the organization.

The inventory 13, or database, is the storage of all information related to the business of the organization. It includes a network data model where all video transmission services are clearly defined with their appropriate relations (which VSP provides the service, which VSP sells the service, technical parameters of each service, etc.). Each video transmission service is subject to cost information and conditions. Contact information as well as operational policies from the customers and VSPs may also be stored as part of an addendum to the inventory. The information in the inventory is readily available for the routing engine and cost engine.

The routing 15 and cost 17 engines are computational algorithms than use certain information of the database to execute specific business logic. The routing engine performs the finding of different routing options (mapping) using the information contained in the inventory. Every routing option comprises a list of video transmission services that are compatible with each other. The cost engine performs the cost assignment to each routing option. Each routing option may have many cost options depending on the business logic applied to the algorithm.

The scheduling management module 19 provides information about the availability of each resource. A resource is the physical representation in the system of the physical infrastructure available for each video transmission service stored in the inventory. A video transmission service could have many resources; different resources can be used within the same date and time. The scheduling manages the availability per resource and prevents the use of resources that had already been reserved (booked).

More specifically, the provision of a video transmission requires not only the booking of items (services) with the required suppliers but also implies the physical reservation of network elements. These network elements represent the electronic components required to transmit/receive a video transmission. Some network elements are antennas, decoders, encoders, fiber loops, video switching equipment, video tape recorders, etc. Each of these network elements is defined in the inventory (database) so that the system can manage them through the schedule management system. A network element is booked once there is a booking. The booking indicates the use of the resource (start date or time and end date or time). The time is usually set in hours, minutes and/or seconds. A network element must be released from a booking when there is a booking cancellation, so that it can be available for future bookings. Each item and its respective network element is booked with the following information: start date and time of the video transmission; end date and time of the video transmission; and appropriate unique identifiers, such as purchase order number and service order number.

The scheduling management module allows a user to book an item (or service) and its respective network element for a certain period of time and within a certain context. A user is then capable of determining of a specific item is already booked or if it is available. The scheduling management module also is preferably adapted to automatically warn a user if an item has already been booked in order to prevent double-booking of elements.

It should also be noted that an item may have several network elements. Consequently, when all of the elements of an item are booked for a certain period of time, the particular item is removed from the list of available items.

Since a video transmission comprises many items, the successful booking of a video transmission will depend on the availability of the items and its network elements. If one of the items cannot be booked, then the customer will have to reschedule the video transmission.

The procurement subsystem 21 provides a set of standard interfaces and forms to get and analyze cost and technical information from each VSP and provide routing and cost options based on particular requirements. Those particular requirements are entered into the system through a quotation (i.e. request for quotation). Procurement makes extensive use of the routing and cost engine through the workflow engine.

The provisioning subsystem 23 provides a set of standard interfaces and forms to reserve, schedule and coordinate compatible video transmission services from a plurality of VSPs. The objective of provisioning is to perform all activities required to provision the network infrastructure requirements for a video transmission service from origin to destination. The specific requirements for a video transmission service are entered into the system through a service order (i.e. request for service).

Both procurement and provisioning are subject to the workflow engine. These two major process oriented modules may trigger different tasks to different users based on the workflow engine.

The billing subsystem 25 provides the necessary tools to issue invoices as well as keep track of payables and receivables. Billing also includes cost conciliation and invoice dispute resolutions.

The hardware controller 27 receives commands from the system and translates them into serial or parallel communications in order to communicate with the various equipments that may be involved in the video transmission service activation. Once the hardware controller interfaces with the equipment, it is also adapted to raise alarms depending on the status of the equipment (bad configuration, not responding, equipment failure, etc.). Some of the equipments that the hardware controller interacts with are: video switching equipment, encoders, decoders, standard converters, etc. It will be appreciated by persons skilled in the art that adapting the hardware controller to raise alarms does not involve any inventive activity.

The ordering subsystem 29 is an important element for the organization. Ordering is where the organization enters and manages much of the information necessary for providing a video transmission service. The organization can keep track of customers and manage relationships with suppliers and trading partners as well. The ordering system preferably features an intuitive graphical user interface (GUI), which helps customer-service representatives complete orders more quickly and accurately and can even provide the capability for customers to place their own orders via Internet (electronic orders). The ordering system also automates some of the data entry that is common to the types of services the organization offers, further reducing the time to enter an order. The ordering system also performs a certain amount of error checking to notify users when required data has been omitted or invalid data has been entered; this functionality helps maintain overall process integrity and helps prevent incorrect/incomplete orders, which can be both costly and time-consuming.

In accordance with a preferred aspect of the invention, there are three ways to enter a service order into the system.

A customer can first turn a quotation into a service order by selecting an option (route and price). Secondly, a customer enters a service order by selecting a special event or rate card. In both cases the customer will select a route specified in the special event or rate card. There is no quotation provided to the customer. Thirdly, a customer or broker operation enters a service order by selecting a route that had been used before by the customer or from the routing table (manual calculated route). In all cases there is a minimum set of data required to enter a service order. Most of this data is already included in the quotation (case 1) or in the special event/rate card (case 2). Since in either case there might be some additional data required, the following is an example of a complete set of data required:

1. Customer: Company name and contact name.

2. Origin (From): A city, site, location, satellite or switching center.

a. If the origin is a Site, please provide address information and connectivity information. If the customer has transmitted from this Site before, it is imperative that this connectivity information is passed into the system. If this information is not available, the system can either quote an SNG vehicle/Uplink truck when available or reject the request for quotation.

b. If the origin is a city, the route engine will perform the quotation response by proposing a default network facility (Switching Center, Teleport) that can be used as an origin.

c. If the origin is a satellite, the following information must be included:

i. Valid satellite administration name, valid satellite ID, Band: C or Ku.

ii. Type of transmission: Analog or Digital

iii. If Digital, the space segment bandwidth in Mhz (normally 9 Mhz)

iv. Will the customer provide the space segment? Yes or No.

d. An origin cannot be a continent, a country, a region, a TBD.

e. Video format and audio format are mandatory. Check the video format at the country of origin. If the video format or audio format selected by the customer at a specific origin is not available, the system will quote the available ones.

f. Service required at the origin (user services): there are some services required at the origin that the customer has to select. These services are known as user services. The following are some of the user services usually provided: tape play out, stand up live position, studio live position, camera & crew, editing facilities, equipment rental, etc.

3. Destination (To): A city, site, location, satellite or switching center.

a. If the destination is the Customer Site, please provide address information and connectivity information. If the customer has received video transmissions at this Site before, it is imperative that this connectivity information is passed into the system. If none of this information is available, the customer and the Broker Sales will be advised to enter the customer connectivity profile.

b. If the destination is a city, the route engine will perform the quotation response by proposing a default network facility (Switching Center, Teleport) that can be used as a destination.

c. If the destination is a satellite, the following information must be included:

i. Valid satellite administration name, valid satellite ID, Band: C or Ku.

ii. Type of transmission: Analog or Digital

iii. If Digital, the transponder space in MHz (normally 9 MHz)

iv. Will the customer provide the space segment? Yes or No.

v. A destination cannot be a continent, a country, a region, a TBD.

vi. Video format and audio format are mandatory. Check the video format at the country of destination. If the video format or audio format selected by the customer at a specific origin is not available, the system will quote the available ones.

4. Start date and time: Start date and time of the video transmission.

5. End date and time: End date and time of the transmission.

6. Route: provides a technical description on how the signal will travel from Origin to Destination naming suppliers and all network facilities and network services required.

7. Additional information:

a. Video service type: unidirectional or bi-directional. For some specific origins and destinations bi-directional service is not available.

b. Number of audio channels: the system uses the default value of 2 audio channels, even if the customer is selecting other values.

8. Special requirements: If apart from the video transmission services there are other requirements. Example: Lighting system, crew, reporters, make-up, etc.

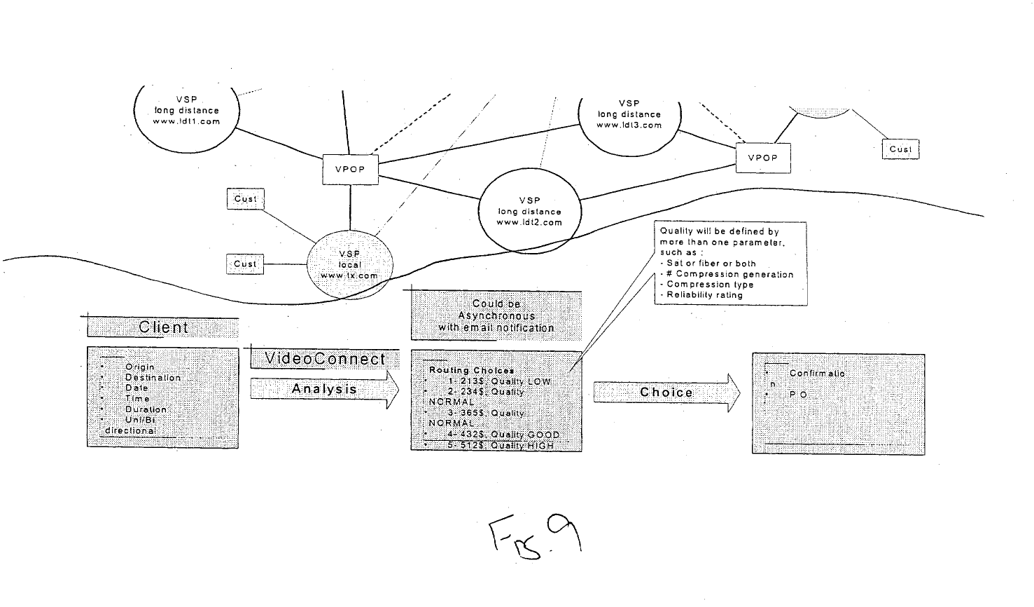

Once a service order is entered, an automatic service order confirmation will be issued by the system after processing the service order. If the confirmation cannot be issued immediately then a notification of service order receipt will be automatically sent to customer by the system; all of the requirements (rules) described above are integrated into a service ordering system, so that the user can seamlessly enter a service order. The intuitive interface guides (like a wizard) the user through the data entry process to ensure that data is correctly defined avoiding potential problems or misunderstanding in the service order processing. In a more schematic way, FIG. 9 shows the criteria selected by the user, the route and cost analysis results, and the selected chosen by the client.

The actual video transmission (service activation), also commonly known as video transmission coordination, is the final stage of a service order. Basically, it involves the interaction of multiple telecommunications systems provided by multiple VSPs to work together to deliver a video from origin to destination. This system enables the management of video transmission coordination and offers support tools for the management of troubleshooting as well.

This module 31 oversees all aspects of the video transmission coordination: before, during and after the transmission. Before the transmission starts, there is a line up process to make sure that all suppliers involved are ready to transmit the video signal. This line up process mainly communicates to the suppliers the activation of the network elements required for a specific video transmission. If a supplier is not ready to activate or is having problems with its network elements, the transmission may be compromised, so troubleshooting will be required. The module guides the user (broker operation) throughout the line-up process indicating which supplier to call and which network elements to activate. If a supplier has an electronic remote interface, the supplier may receive this communications electronically. The video transmission coordination module 31 coordinates all of these activities. The customer is also involved in the line up process to make sure that they can send/receive the video signal. Once the transmission is underway, the system/broker operation will contact the destination to ascertain that they are receiving the correct video signal (material) and that the signal quality is as expected. If not, the system/broker operation must initiate troubleshooting of the video transmission. When the destination is not receiving the correct video signal (material) or the signal quality is not as expected, the system/broker operation initiates a troubleshooting. The troubleshooting consists of several communications between the system/broker operation, the suppliers involved in the video transmission and the customer that requested the service. All these communications are aimed at identifying the technical problem and taking the necessary corrective measures to solve it. All communications are logged by the system, so that they can be included in the troubleshooting report. In cases where the technical problem(s) cannot be resolved within the allotted time (or to the customer's satisfaction), the system/broker operation will find/offer alternatives routes for the customer. At this time, the customer will have the following options: accept an alternative route from the system/broker operation; cancel the video transmission (service order cancellation); accept an extension of the service order, so that more time is given to resolve the problem (service order amendment); or accept to re-schedule the video transmission (new service order).

Remote Electronic Interfaces

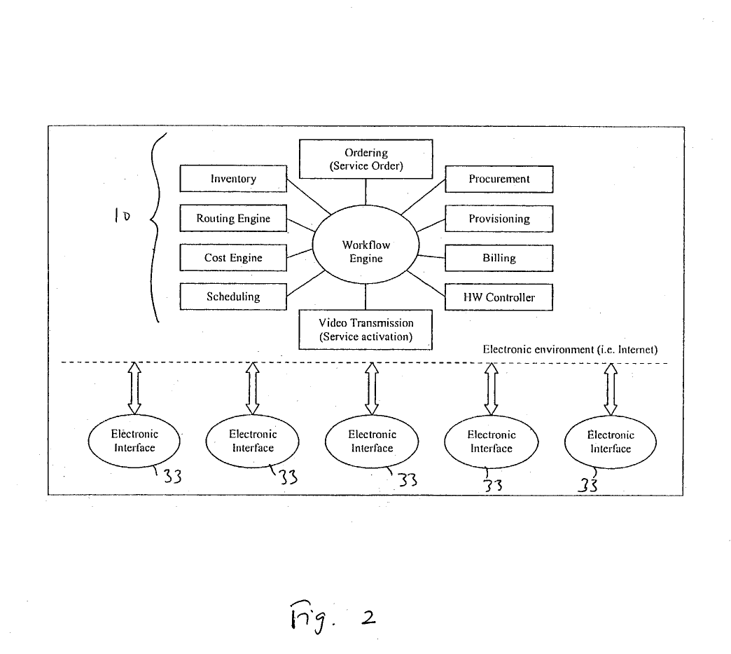

Remote electronic interfaces 33 are also available to remotely interact with the system. These remote electronic interfaces, shown in FIG. 2, enable the access to certain modules of the system to enable full interactivity, especially with the ordering system as we mentioned earlier.

The electronic interface enables a customer of the organization to: submit a quotation, enter a service order, get notifications of the status of a service order, enter service order amendments, update profile information, etc. The electronic interface enables also a supplier (i.e. VSPs) of the organization to: submit new inventory (services and cost), confirm service bookings (reservations), get notification of the status of a booking, update profile information, etc.

Operability Between Multiple Systems

The overall system 10, 10′ of the present invention can be distributed among different organizations that perform procurement and provisioning of video transmission services from a plurality of video service providers. In this scenario each organization will maintain and manage its own systems and subsystems, but multiple organizations may select to exchange inventories of video transmission services, i.e. exchanging information between their respective databases. This is enabled by selecting the items of the inventory that will be transferred from one organization to the other. Since both organizations share the same network data model (since it is the same system), the transfer of inventories is seamless.

Database

One important aspect in achieving the system and method of the present invention is the creation of a unified global network model that represents the multiple VSP networks, and which connected all of these together in a single coherent super-network while faithfully representing the pricing, routing and other characteristics of the sub networks. At the same time, the model must be sufficiently lightweight so that routing calculations based on the model can be quickly and efficiently completed. Finally, the model provides for variable transactional and visibility privileges, so that pre-existing privileged access and/or rates may continued to be accessed (e.g. a customer with a preferential rate with Bell will continue to benefit from this rate).

The design of a network model and functioning of the routing engine is critically dependant on the ability to quickly and efficiently access data defining the network element characteristics. Therefore, a globally distributed data infrastructure to store all routing, pricing and other characterizing information is established. This infrastructure is capable of serving the required information within seconds to the routing engine or to a user located anywhere in the world, over an Internet connection. Finally the infrastructure provides full control of security and confidentiality of private VSP data.

Route

The present invention makes use of a single coherent and comprehensive video network model in order to represent all the services used within a video network. Then, a routing engine, for a desired start point, end point and certain criteria (e.g. price, time, date, quality, length, etc . . . ), computes different distinct routes. Each route consists of a sequential list of services required to transport the video signal from the origin to a destination. Routes calculated by the route engine are then post-processed by other components of the system of the present invention.

The route engine is software used to calculate different possible routes used to transport a video signal from any given origin to any given destination. The route engine is a Java-based system that uses combinatory mathematics to compute desired result. The engine is divided into three parts: Video Network Model, Java Graph Framework and Routing Engine Business Logic.

Video Network Model

The video network model is the structural representation of a Video Network. The route engine is using information from that model to calculate routes.

Vertices

| | | Incoming | Outgoing |
|---|---|---|---|
| Name | Description | edge | edge |
| Terrestrial Network | This could either be a switching | Terrestrial- | Terrestrial- |
| Facility (TNF) | center, an earth station or any | transport, | transport, |
| | non-movable terrestrial facility | Downlink- | Uplink- |
| | where a video service is | transport, | transport, |
| | provided. | Subnet- | Subnet- |
| | | transport | transport |
| Transportable | This could either be a mobile | | Uplink- |
| Terrestrial Network | truck or any movable terrestrial | | transport |
| Facility (TTNF) | facility where a video service is | | |
| | provided. | | |
| Satellite/Beam | This is a spatial facility that | Uplink- | Downlink- |
| | provides transponder space | transport | transport |
| | service using a specific band (C, | | |
| | KU). One satellite could have | | |
| | one or more footprint. | | |
| Subnet | It represents an implicitly | Subnet- | Subnet- |
| | interconnection between different | transport | transport |
| | terrestrial network facilities. | | |
| | Representing that | | |
| | interconnection without the | | |
| | subnet requires a lot more | | |
| | edges, because you need to link | | |
| | all TNF to each other instead of | | |
| | linking all them to the subnet. | | |

Edges

| Name | Description | From Vertex | To Vertex |
|---|---|---|---|
| Terrestrial- | This is a fiber, microwave, copper | Terrestrial | Terrestrial |
| transport | or any terrestrial medium used to | Network | Network |
| | transport a video signal. | Facility | Facility |
| Uplink- | This is a medium used to transport | Terrestrial | Footprint |
| transport | a video signal from terrestrial | Network | |
| | facility (transportable or not) to a | Facility, | |
| | specific footprint of a satellite. | Transportable | |
| | | Terrestrial | |
| | | Network | |
| | | Facility | |
| Downlink- | This is a medium used to transport | Footprint | Terrestrial |
| transport | a video signal from specific | | Network |
| | footprint of a satellite to a terrestrial | | Facility, |
| | facility (transportable or not). | | Transportable |
| | | | Terrestrial |
| | | | Network |
| | | | Facility |
| Subnet- | This is an implicit terrestrial- | Subnet | Terrestrial |
| transport | transport. It represents the relation | | Network |
| | between one Terrestrial Network | | Facility |
| | Facility and a subnet. | Terrestrial | Subnet |
| | | Network | |
| | | Facility | |

Note:
All the above edges are used to transport a video signal. This signal is
defined using a specific video format. Each of these transports is compatible with
one unique video format. The routing engine insures that this compatibility is
respected (it never goes through a transport that supports a different video format
than the one used by the video signal).

Network Service

| Name | Description | Provided at | Attributes |
|---|---|---|---|
| Switching | This service allows a signal | Terrestrial Network | |
| | coming in a TNF to be | Facility | |
| | switching to any outgoing | | |
| | transport (except the | | |
| | sequence downlink, uplink | | |
| | which is handle by turn | | |
| | around) | | |
| Space | This service allows a signal | Satellite/Beam | |
| Segment | to be sent to a footprint. In | | |
| | other to transmit the video | | |
| | signal correctly, the uplink- | | |
| | transport and downlink- | | |
| | transport shall use the | | |
| | same transponder space. | | |
| Standard | A video signal is defined | Terrestrial Network | Video format |
| Conversion | using a specific video | Facility, | from, |
| | format. The Standard | Transportable | Video format to |
| | Conversion Service allows | Terrestrial Network | |
| | the conversion of a video | Facility | |
| | signal from one video | | |
| | format to another video | | |
| | format. This service is | | |
| | required when we want to | | |
| | transmit a video signal | | |
| | defined in a different format | | |
| | than the one supported by | | |
| | the transport. | | |
| Turn Around | This service allows a signal | Terrestrial Network | List of |
| | coming from a downlink- | Facility | (downlink- |
| | transport in a TNF to be | | transport, uplink- |
| | sent to an uplink-transport. | | transport) |

Java Graph Framework (JGF)

JAVA GRAPH FRAMEWORK (JGF) is a graph theoretical library composed of generic reusable components used to resolve combinatorial mathematics problems. This framework is composed of three types of object: data model, utility and algorithms. In this section we will explain the difference between each of them and their usage.

Data Model

JGF Data model classes are used to store information relating to the graph. These classes do not contain any algorithms or complex logic. All classes of that category derive from GraphObject. GraphObject has a name, a unique identifier and a dictionary of data.

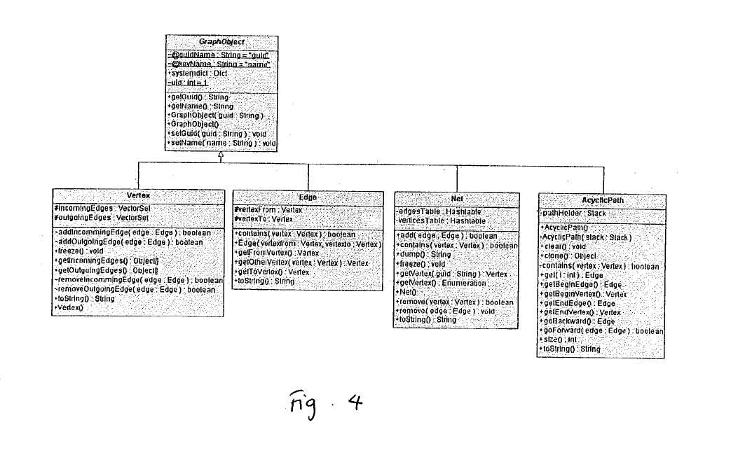

The data model class hierarchy for the JGF is shown in FIG. 4. At the root is the abstract class GraphObject. Vertices are simple objects that can have names and other properties; an edge is a connection between two vertices. The class Net is the container where all the vertices and edges live. There are multiple kinds of graphs, but to keep it simple we only model the less restrictive kind (the Net). A Net could support: multiple parallel edges, loops (edges that from and to are equal) and cycle. Using method of the three previous classes you could traverse the Net. AcyclicPath class is used to represent a particular traversal from a vertex source to a vertex destination. Keep in mind that by definition an acyclic path is a path without cycle. Although, there is many types of path to keep the JGF simple we only implement AcyclicPath.

Utility

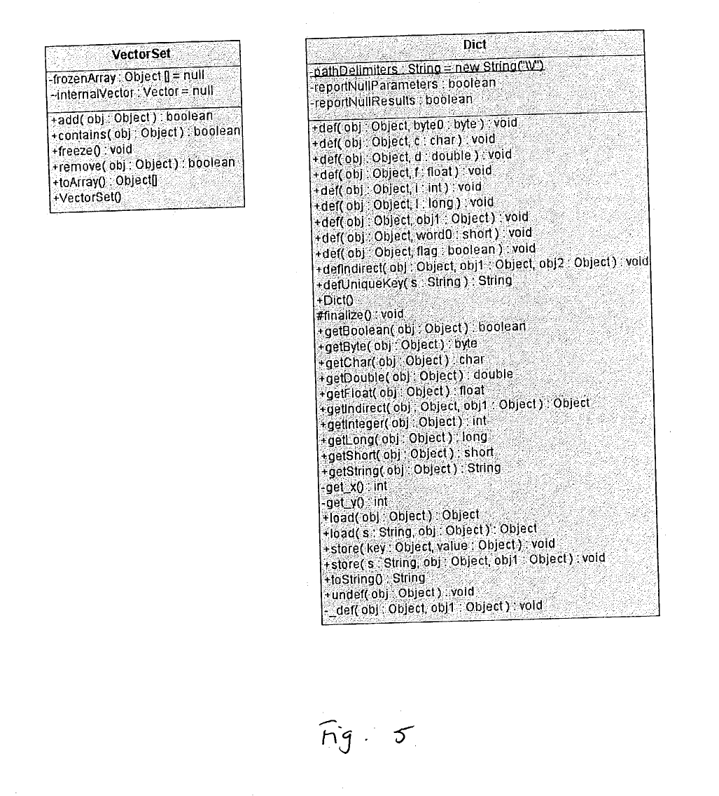

Referring now to FIG. 5, utility classes are used to manipulate data structures that are not directly link with Graph Theory. For example, a dictionary class is used to store a catalog of data. It is possible to use a dictionary in a different context than the graph theory. That is why we want defined them in a separate package. The flexibility of the dictionary is that we can add attribute to the dictionary without having to recompile the code. VertorSet is the other utility class used to store a set of vector. You could freeze a VectorSet to optimize the read access.

Algorithm

JGF contains algorithms that perform Network traversal. To ease the comprehension of the traversal algorithm, we are using the metaphor of a walker. A walker is an object that walks through a Network. The walker starts to walk at a source vertex and has the objective to collect all possible paths to a specific destination. Multiple walkers could be created with different walking strategy (for example: depth-first search or breath-first search). We can apply walk constraints to these walkers. These constraints will prevent the walker from traversing specific edges.

JGF supports multiple walkers traversing the network simultaneously. This parallelism improves the response time. We are using a read-only copy of the network in memory. By having a read only copy the walkers do not need to perform synchronized operations, which are really expensive. Because of that optimization, the copy of the network must be replaced periodically.

Routing Engine Business Logic

The route calculation process logic relies on: the route calculation parameters and the routing rules.

Route Calculation Parameters

To compute a route in a video network multiple parameters are required:

| Name | Description | Possible Value |
|---|---|---|
| Origin | This is the vertex where the route | Terrestrial Network Facility, |
| | calculation starts. | Transportable Terrestrial Network |
| | | Facility, Footprint |
| Source | This is the video format used when | NTSC Analog, |
| Video Format | the video signal is input at the | NTSC Digital, |
| | source. | PAL Analog, |
| | | PAL Digital, |
| | | SECAM Analog, |
| | | SECAM Digital |
| Origin | This is a Boolean that indicates if it | True, False |
| Transponder | is Invidex or the end-customer that | |
| Space | paid for the transponder space. | |
| Provided By | | |
| Invidex | | |
| Origin User | User service provided at the | |
| Service | source. If the origin is a footprint | |
| | the user service will be set to the | |
| | transponder space. | |
| Destination | This is the vertex where the route | Terrestrial Network Facility, |
| | calculation ends. | Footprint |
| Destination | This is the video format used when | NTSC Analog, |
| Video Format | the video signal is output at the | NTSC Digital, |
| | destination. | PAL Analog, |
| | | PAL Digital, |
| | | SECAM Analog, |
| | | SECAM Digital |
| Destination | This is a Boolean that indicates if it | True, False |
| Transponder | is Invidex or the end-customer that | |
| Space | paid for the transponder space. | |
| Provided By | | |
| Invidex | | |
| Destination | If the destination is a footprint the | |
| User Service | user service will be set to the | |
| | transponder space. | |

Routing Rules

To compute routes, the routing engine uses specific rules that make it evaluate if a transport is a valid one. It is also these rules that make it decide if there is a specific network service required using a transport. All rules are classified in two different classes: optional and mandatory.

All walkers traverse the video network without producing cycle. For each rule stated bellow, a WalkConstraint implementation will be created to store that logic. During the traversal of the network every rule (WalkConstraint) is evaluated. The distribution of the logic in many objects improves the readability and scalability of the application. With this approach new types of vertex and their constraints could be added to the application without having to change the existing rules.

Optional Rules

These optional rules are specified as parameter of the route calculation.

| Name | Description |
|---|---|
| MaxNbResult | The routing engine will stop computing after it |
| | found this number of routes. |
| MaxSizeOfPath | Path longer than this size will be rejected. |
| TimeToProcessQuery | The routing engine will stop computing after it |
| | found this amount of time. |

Mandatory Rules

| | | | | | Network |
|---|---|---|---|---|---|
| | | | | | Service |
| Name | Description | Edge-from | Vertex | Edge-to | Required |
| Transponder- | Going through a downlink after an uplink | Uplink-transport | Footprint | Downlink-transport | Transponder- |
| Rule | requires that the downlink is using the | | | | Space |
| | same transponder-space than the | | | | |
| | uplink. Note: Transponder spaces at the | | | | |
| | origin and destination are optional | | | | |
| | depending if the client provides himself | | | | |
| | the transponder space. | | | | |
| TurnAround- | Going through a downlink-uplink | Downlink-transport | Terrestrial | Uplink-transport | Turn-Around |
| Rule | sequence requires that the TNF have a | | Network | | |
| | turnaround service defined for that | | Facility | | |
| | downlink-uplink sequence. | | (TNF) | | |
| Switching- | Going from one transport to another | Terrestrial-transport | TNF | Uplink-transport | Switching |
| Rule | transport in a TNF requires Switching | Terrestrial-transport | TNF | Terrestrial-transport | Switching |
| | (except for sequence uplink-downlink | Terrestrial-transport | TNF | Subnet-transport | Switching |
| | which is handle by the turn around rule) | Downlink-transport | TNF | Terrestrial-transport | Switching |
| | | Downlink-transport | TNF | Subnet-transport | Switching |
| | | Subnet-transport | TNF | Uplink-transport | Switching |
| | | Subnet-transport | TNF | Terrestrial-transport | Switching |
| | | Subnet-transport | TNF | Subnet-transport | Switching |
| Standard | Converting the video format of a signal requires the | ANY | Terrestrial | ANY | Standard |
| Conversion- | standard conversion. This standard conversion shall | | Network | | Conversion |
| Rule | convert the current video format of the signal to the one | | Facility | | |
| | required by the transport. | ANY | Transportable | ANY | Standard |
| | Only one standard conversion could be done in the | | Terrestrial | | Conversion |
| | same route. | | Network | | |
| | The only conversion allowed is converting from the | | Facility | | |
| | video format of the signal input to the video format of the | | | | |
| | signal output. | | | | |
| | By consequence, if the video format of the signal input | | | | |
| | and output are the same there is no standard conversion | | | | |
| | allowed. | | | | |
| Video Format | You could only send a video signal to a transport if its | ANY | ANY | ANY | |
| | video format is the same than the one supported by the | | | | |
| | transport. | | | | |
| AcyclicPath | A path shall not have any cycle. | | | | |

In conclusion, the route engine is a software module that uses a Graph Theory framework called JFC. Using the Video Network Model, route calculation parameters and different routing rules, the route engine is able to compute different routes based on predetermined criteria.

Costing Engine

An automated software engine is intended to resolve the calculation of time-sensitive cost options. Once all items are clearly identified and defined, the automated software engine analyzes each item and the number of sellers. The following block diagram explains the relation between “items”, “bundles”, “sellers” and “rate cards” (data universe).

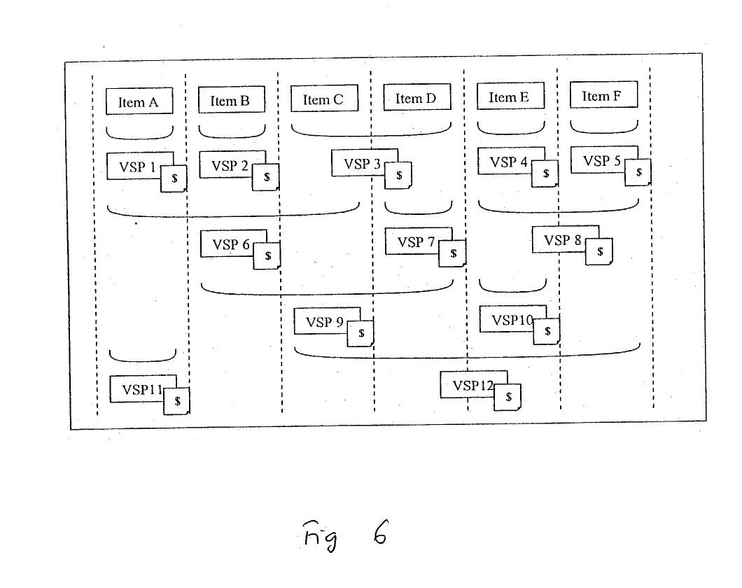

As it appears in FIG. 6, some items can be sold individually (item A sold by VSP1 and VSP11, item B sold by VSP2, item D sold by VSP7, item E sold by VSP4 and VSP1 0, item F sold by VSP 5) and some items can be sold as part of a bundle (VSP6 sells a bundle containing items: A, B and C; VSP8 sells a bundle containing item E and F; VSP9 sells a bundle containing items B, C and D; VSP12 sells a bundle containing items C, D, E and F).

The automated software engine takes the data model to reproduce all cost options available. Every cost option must include a set of VSPs that can sell each of the items from A to F as either single items or bundles. For example, for the diagram shown above, the following are valid cost options: buy items from VSP1, VSP2, VSP3, VSP4 and VSP5; buy items from VSP 6, VSP7, VSP4 and VSP5; buy items from VSP6, VSP7 and VSP8; etc.

Once all cost options are calculated, the automated software engine will execute the rate card cost calculation. Each rate card has been modeled into a template. Each template has a cost algorithm that may apply depending on the duration of the video transmission.

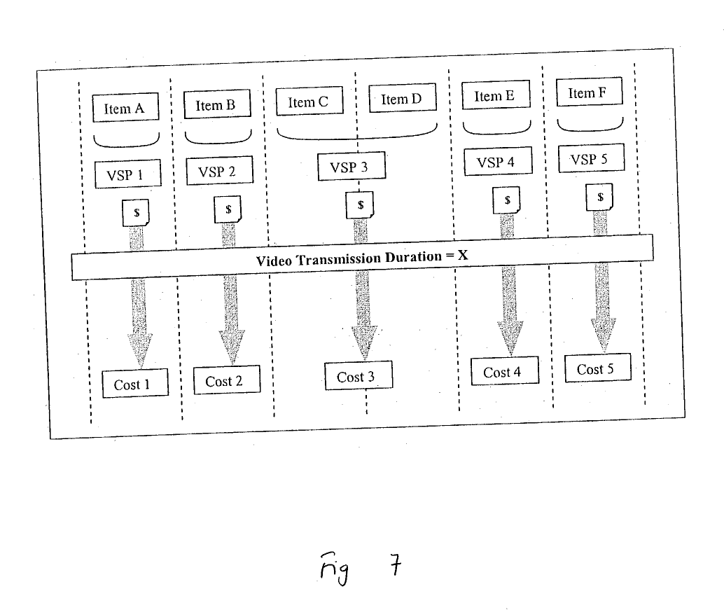

FIG. 7 represents the flow of the cost calculation per cost option.

Once all costs have been calculated the automated software engine will finalize the cost calculation by adding all individual cost into the appropriate cost option.

Rate Card Templates

This section is intended to provide an overview of the rate card templates. In the video transmission industry, different VSPs use different rate cards. Most of the rates are time-sensitive. Rate card templates are used to provide generic solutions to the costing problem in the industry. This invention should not be limited to the rate card templates described but it should allow the aggregation of future rate card templates.

1. Minimum charge and increment charge template: items that are sold at a minimum time (time interval) for a minimum charge ($) and additional increments (time interval) are sold at an increment charge ($/time interval). Examples:

a. A service with the following cost: minimum of 10 minutes at $100. Additional increments of 5 minutes are allowed at $50 per each 5 minutes.

i. 5 minutes of service will cost $100.

ii. 15 minutes of service will cost $100+$50×1=$150

iii. 20 minutes of service will cost $100+$50×2=$200

iv. 30 minutes of service will cost $100+$50×4=$300

v. In the rate card template: minimum time=10 minutes, minimum charge=$100, increment time=5 minutes, increment charge=$50 per each 5 minutes.

b. A service with the following cost: $10 per each 1 minute.

i. 5 minutes of service will cost $10×5=$50

ii. 10 minutes of service will cost $10×10=$100

iii. 30 minutes of service will cost $10×30=$300

iv. In the rate card template: minimum time=1 minute, minimum charge=$10, increment time=1 minute, increment charge=$10 per each 1 minute.

c. A service with the following cost: $100 (one-time fee).

i. 5 minutes of service will cost $100

ii. 10 minutes of service will cost $100

iii. 30 minutes of service will cost $100

iv. In the rate card template: minimum time=∞, minimum charge=$100, increment time=0, increment charge=0.

2. Window template: items that are sold within time slots with the upper value (time interval) defining each window slot. Examples:

a. A service with the following cost: window slot 1=up to 15, minutes @$20, window slot 2=up to 30 minutes @$42, window slot 3=up to 45 minutes @$65, window slot 4=up to 60 minutes @$112, window slot 5=up to 75 minutes @$120.

i. 5 minutes of service will cost $20

ii. 10 minutes of service will cost $20

iii. 15 minutes of service will cost $20

iv. 20 minutes of service will cost $42

v. 25 minutes of service will cost $42

vi. 35 minutes of service will cost $65

vii. 45 minutes of service will cost $65

viii. 55 minutes of service will cost $112

ix. 70 minutes of service will cost $120

x. In the rate card template:

| | | |
|---|---|---|
| 1. Window slot 1 | 15 minutes | $20 |
| 2. Window slot 2 | 30 minutes | $42 |
| 3. Window slot 3 | 45 minutes | $65 |
| 4. Window slot 4 | 60 minutes | $112 |
| 5. Window slot 5 | 75 minutes | $120 |

Cost Calculation Business Logic

Some business logic should be applied to the automated software engine in order to produce the desired cost options. This business logic enables the management of the automated software engine by refining the cost analysis. The following parameters are used by the automated software engine to deliver the desired cost options:

1. Minimize the number of VSPs involved in the cost option: In the video transmission industry, there are a number of VSPs that can integrate video transmission services by reselling services from other VSPs. This rule will communicate the software engine to select the minimum number of VSPs to complete a transaction. In this case, the software engine should prioritize the service bundles in order to minimize the number of VSPs. The user should provide the maximum number of VSPs. The automated software engine should return all cost options available with less or equal to the number of VSPs selected.

2. Provide the cheapest cost option: The cheapest cost option can be provided by comparing all different cost options and selecting the one with the lower price. The user should provide a target amount ($). The automated software engine should return all cost options available under or equal to the target amount.

3. Provide cost options with preferred VSPs: Selecting preferred VSPs beforehand will narrow the number of cost options, but it is an important tool when trying to allocate volume to some preferred VSPs in order to gain interesting level of discounts. The user should provide the list of preferred VSPs. The automated software engine should return all cost options where those VSPs are present. There might be cost options with several VSPs involved but only one is a preferred VSP.

4. Combinations of business logic: The automated software engine should allow the combinations of rules described above.

5. Provide routing options using preferred items: Preferred items are any of the items that participate in the routing of a video transmission (network services). The user may want to receive a routing option using a specific satellite or switching center.

Although the present invention has been explained hereinabove by way of a preferred embodiment thereof, it should be pointed out that any modifications to this preferred embodiment within the scope of the appended claims is not deemed to alter or change the nature and scope of the present invention.

1. A system for the management of procurement and provisioning of video transmission services, comprising:
(a) a database containing information related to video transmission services provided by a video service provider for a plurality of video service providers;
(b) a routing engine operatively associated with said database for calculating at least one route for routing a video service between video service providers based on selectable criteria;
(c) a cost engine operatively associated with said database for calculating a cost associated with each of said at least one route calculated by said routing engine;
(d) an ordering module for entering said criteria; and
(e) a video transmission coordination module for delivering a video transmission service from origin to destination.

2. A system according to claim 1, wherein said system further includes a scheduling module for providing information relating to availability of video transmission services and for reserving video transmission services based on a selected route.

3. A system according to claim 1, wherein said system further includes a billing module for billing a client for a video transmission service.

4. A system according to claim 1, wherein said ordering module further includes a graphical user interface for easing interaction with said system.

5. A system according to claim 1, wherein said system further includes a workflow engine for organizing and managing the flow of information within said system.
